(19) United States
(12) Patent Application Publication
(10) Pub. No.: US 2025/0087872 A1
(43) Pub. Date: Mar. 13, 2025

(54) Electronic Device with Fan-Integrated Antenna

(71) Applicant: Apple Inc., Cupertino, CA (US)

(72) Inventors: Killian J. Poore, San Jose, CA (US); Jas Mukesh Gajaria, Sunnyvale, CA (US); Jiangfeng Wu, San Jose, CA (US); Mei-Li Chi, San Jose, CA (US); Jason C. Sauers, Sunnyvale, CA (US); Siwen Yong, San Francisco, CA (US); Yi Jiang, Cupertino, CA (US); Shirley S. Lu, Sunnyvale, CA (US)

(21) Appl. No.: 18/626,226

(22) Filed: Apr. 3, 2024

Related U.S. Application Data
(60) Provisional application No. 63/581,246, filed on Sep. 7, 2023.

(51) Int. Cl. H01Q 1/27; H01Q 1/38; H01Q 1/44; H01Q 1/48; H05K 7/20

(52) U.S. Cl. CPC H01Q 1/273; H01Q 1/38; H01Q 1/44; H01Q 1/48; H05K 7/20145

(57) ABSTRACT

An electronic device such as a head-mounted display device may include an antenna that radiates through a cover. The antenna may have a ground and an antenna resonating element layered onto the cover. The ground may include conductive structures separated from the resonating element by a volume. The device may include a fan that conveys air through a vent in a chassis of the electronic device through a tunnel. The tunnel may be free from conductive material and may extend through the volume of the antenna. The fan may include blades enclosed within metal walls. A conductive mesh may be coupled between the metal walls and may separate the blades from the tunnel. This may serve to extend the volume of the antenna to also include at least some of the volume of the fan, thereby maximizing efficiency bandwidth of the antenna without sacrificing thermal dissipation by the fan.

This application claims the benefit of U.S. Provisional Patent Application No. 63/581,246, filed Sep. 7, 2023, which is hereby incorporated by reference herein in its entirety.

### FIELD

This relates generally to electronic devices, including electronic devices with wireless communications capabilities.

### BACKGROUND

Electronic devices often have displays that are used to display images to users. Such devices can include head-mounted displays and can have wireless circuitry with antennas.

If care is not taken, head-mounted displays can be subject to excessive thermal loads. It can also be challenging to incorporate antennas that exhibit satisfactory levels of wireless performance into head-mounted displays.

### SUMMARY

A head-mounted device may have a housing. The housing may have an inner conductive chassis mounted to an outer conductive chassis. A logic board may be mounted to the inner conductive chassis. Left and right displays may be mounted to the logic board and may display images at a rear of the device. A cover may be mounted to the outer conductive chassis at the front of the device. The cover may have a compound or three-dimensional curvature. A front-facing display may be mounted to the cover and may display images through the cover.

The device may have wireless circuitry with an antenna. The antenna may have an antenna resonating element layered onto the cover. The antenna may have an antenna ground separated from the antenna resonating element by an antenna volume. The antenna may convey radio-frequency signals through the cover. The antenna ground may include conductive structures in the device.

The outer chassis may have an air vent. A fan may be mounted to the logic board. The fan may include a fan housing. The fan housing may have walls that define a fan cavity. The fan may have blades disposed within a central portion of the fan cavity. The fan cavity may include a tunnel that extends from the central portion of the fan cavity to the vent. The blades may convey air through the vent via the tunnel. The tunnel may extend through the antenna volume. The tunnel may be interposed between the conductive structures and the antenna resonating element. The walls of the fan housing may be free from conductive materials within the antenna volume.

The walls may include conductive walls overlapping the central portion of the fan cavity. A conductive mesh may be coupled between the conductive walls. The conductive mesh may allow air to pass between the central portion of the fan cavity and the tunnel while being electromagnetically opaque at the frequencies of the antenna. In this way, the antenna may be integrated with the fan, such that the antenna volume is extended to also include a portion of the antenna cavity. This serves to maximize the efficiency bandwidth of the antenna without sacrificing thermal dissipation capabilities of the fan.

### BRIEF DESCRIPTION OF THE DRAWINGS

FIG. 1 is a schematic diagram of components in an illustrative electronic device in accordance with some embodiments.

FIG. 2 is a cross-sectional top view of an illustrative electronic device in accordance with some embodiments.

FIG. 3 is a schematic diagram of illustrative wireless circuitry having an antenna in accordance with some embodiments.

FIG. 4 is a circuit diagram of illustrative wireless circuitry having transceivers that convey radio-frequency signals using antennas in accordance with some embodiments.

FIG. 5 is a front view of an illustrative electronic device having antennas disposed around the periphery of a cover glass assembly in accordance with some embodiments.

FIG. 6 is a side view of an illustrative electronic device having antennas disposed around the periphery of a cover glass assembly in accordance with some embodiments.

FIG. 7 is a front view of an illustrative fan in an electronic device in accordance with some embodiments.

FIG. 8 is a cross-sectional side view of an illustrative electronic device having an antenna that is integrated into a fan in accordance with some embodiments.

### DETAILED DESCRIPTION

Electronic devices may be provided with components such as antennas. The electronic devices may include portable electronic devices, wearable devices, desktop devices, embedded systems, and other electronic equipment. Illustrative configurations in which the electronic devices include a head-mounted device may sometimes be described herein as an example. The head-mounted device may have first and second rear-facing displays and a front-facing display. The device may have a housing with a cover at a front side of the device. The cover may have a compound three-dimensional curvature. The device may include an outer conductive chassis and an inner conductive chassis. A main logic board may be mounted to the inner conductive chassis. The first and second rear-facing displays may be mounted to the logic board.

The device may include wireless circuitry with an antenna that radiates through the cover. The antenna may have an antenna resonating element layered onto the cover. The antenna may have an antenna ground. The antenna ground may include conductive structures separated from the antenna resonating element by a cavity. The device may include a fan that conveys air through a vent in the outer chassis. The fan may include a shaft that extends from blades of the fan to the vent. The shaft may extend through the cavity. The shaft may be free from conductive material to extend the cavity to the conductive structures through the fan. This may serve to maximize the efficiency bandwidth of the antenna without sacrificing thermal dissipation performance of the fan.

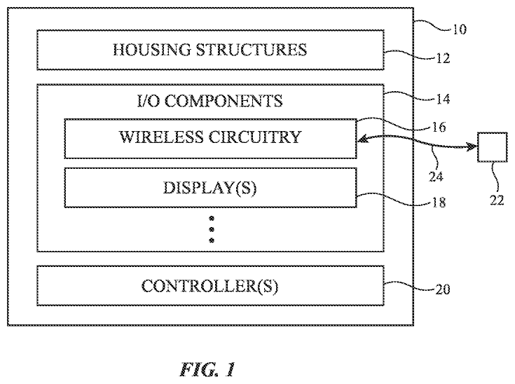

FIG. 1 shows an illustrative electronic device 10. Device 10 may be operated in a system that includes external equipment 22 other than device 10. In some implementations that are described herein as an example, device 10 may include a head-mounted device (sometimes referred to herein as a head-mounted display device or simply a head-mounted display). If desired, device 10 may include a portable electronic device such as a laptop computer, a tablet computer, a media player, a cellular telephone, or a wearable electronic device such as a wristwatch, a pendant or bracelet, headphones, an earpiece, a headset, or other small portable device. Device 10 may also be larger device such as a desktop computer, display with or without an integrated computer, a set-top box, or a wireless access point or base station. If desired, device 10 may be integrated into a larger device or system such as a piece of furniture, a kiosk, a building, or a vehicle.

As shown in FIG. 1, device 10 may include a housing formed from one or more housing structures 12 (sometimes referred to herein as housing members 12). In implementations where device 10 is a head-mounted device, housing structures 12 may include support structures that are mountable or wearable on a user's head (sometimes referred to herein as head-mounted support structures), thereby allowing a user to wear device 10 while using or operating device 10.

The head-mounted support structures in housing structures 12 may have the shape of glasses or goggles and may support one or more lenses that align with one or more of the user's eyes while the user is wearing device 10. The head-mounted support structures in housing structures 12 may include one or more rigid frames that help to provide mechanical integrity, rigidity, and/or strength to device 10 during use. In some implementations that are described herein as an example, the one or more rigid frames are formed from conductive material. The rigid frame(s) may therefore sometimes be referred to herein as conductive frame(s).

If desired, housing structures 12 may include other housing structures or housing members disposed on (e.g., layered on or over, affixed to, etc.) and/or overlapping some or all of the conductive frame(s) (e.g., dielectric structures, rubber structures, ceramic structures, glass structures, fiber composite structures, foam structures, sapphire structures, plastic structures, cosmetic structures, etc.). These other housing structures may, for example, support one or more components in device 10, may help to protect the components of device 10 from damage or contaminants, may help to allow device 10 to be worn comfortably on the user's head, may help to hide portions of the conductive frame from view, may contribute to the cosmetic or aesthetic appearance of device 10, etc.

Device 10 may include input/output (I/O) components such as I/O components 14. I/O components 14 may allow device 10 to provide output and/or other information to the user of device 10 or other entities and/or may allow device 10 to receive user input and/or other information from the user and/or other entities. I/O components 14 may include one or more displays such as displays 18. Displays 18 may emit light (sometimes referred to herein as image light) that is provided to the user's eyes for viewing. The light may contain images. The images may contain image pixels. Many images may be provided over time in a sequence (e.g., as a video). The displays 18 in device 10 may include, for example, left and right displays. The left display may provide light to a user's left eye whereas the right display may provide light to the suer's right eye while the user wears device 10 on their head.

I/O components 14 may also include wireless circuitry such as wireless circuitry 16 (sometimes referred to herein as wireless communication circuitry 16). Wireless circuitry 16 may transmit radio-frequency signals 24 to external equipment 22 and/or may receive radio-frequency signals 24 from external equipment 22. External equipment 22 may include another device such as device 10 (e.g., another head-mounted device, a desktop computer, a laptop computer, a cellular telephone, a tablet computer, a tethered computer, etc.), a peripheral device or accessory device (e.g., a user input device, a stylus, a device that identifies user inputs associated with gestures or motions made by a user, a gaming controller, headphones, etc.), remote computing equipment such as a remote server or cloud computing segment, a wireless base station, a wireless access point, and/or any other desired equipment with wireless communications capabilities. In implementations that are described herein as an example, external equipment 22 includes at least first and second peripheral devices such as left and right headphone speakers or earbuds. The earbuds may be worn by a user to provide audio content to the user's ears while the user is wearing device 10 on their head. Wireless circuitry 16 may transmit the audio content to the earbuds using radio-frequency signals 24.

I/O components 14 may also include other components (not shown) such as sensors, haptic output devices (e.g., one or more vibrators), non-display light sources such as light-emitting diodes, audio devices such as speakers for producing audio output, wireless charging circuitry for receiving wireless power for charging a battery on device 10 and/or for transmitting wireless power for charging a battery on other devices, batteries and/or other energy storage devices, buttons, mechanical adjustment components (e.g., components for adjusting one or more housing structures 12 to allow device 10 to be worn comfortably on a user's head and/or on other user's heads, which may have different geometries), and/or other components.

Sensors in I/O components 14 may include image sensors (e.g., one or more visible and/or infrared light cameras, binocular three-dimensional image sensors that gather three-dimensional images using two or more cameras in a binocular configuration, sensors that emit beams of light and that use two-dimensional image sensors to gather image data for three-dimensional images from light spots that are produced when a target is illuminated by the beams, light detection and ranging (lidar) sensors, etc.), acoustic sensors such as microphones or ultrasonic sensors, gaze tracking sensors (e.g., an optical system that emits one or more beams of infrared light that are tracked using the image sensor after reflecting from a user's eyes while wearing device 10), touch sensors, force sensors (e.g., capacitive force sensors, strain gauges, resistive force sensors, etc.), proximity sensors (e.g., capacitive proximity sensors and/or optical proximity sensors), ambient light sensors, contact sensors, pressure sensors, moisture sensors, gas sensors, magnetic sensors, motion sensors for sensing motion, position, and/or orientation (e.g., gyroscopes, accelerometers, compasses, and/or inertial measurement units (IMUs) that include two or more of these), and/or any other desired sensors.

Device 10 may also include one or more controllers 20 (sometimes referred to herein as control circuitry 20). Controller(s) 20 may include processing circuitry and storage circuitry. The processing circuitry may be used to control the operation of device 10 and may include one or more processors such as microprocessors, digital signal processors, microcontrollers, host processors, application specific integrated circuits, baseband processors, graphics processing units, central processing units (CPUs), etc. The storage circuitry in controller(s) 20 may include one or more hard disks or hard drives storage, nonvolatile memory (e.g., electrically-programmable-read-only memory configured to form a solid-state drive), volatile memory (e.g., static or dynamic random-access-memory), etc. If desired, controller(s) 20 may be configured to perform operations in device 10 using hardware (e.g., dedicated hardware or circuitry), firmware, and/or software. Software code for performing operations in device 10 may be stored on storage and may be executed by processing circuitry in controller(s) 20.

Controller(s) 20 run software on device 10 such as one or more software applications, internet browsers, gaming programs, voice-over-internet-protocol (VOIP) telephone call applications, social media applications, driving or navigation applications, email applications, media playback applications, operating system functions, etc. To support interactions with external equipment 22, controller(s) 20 may implement one or more communications protocols associated with (wireless) radio-frequency signals 24. The communications protocols may include internet protocols, wireless local area network protocols (e.g., IEEE 802.11 protocols—sometimes referred to as Wi-Fi®), protocols for other short-range wireless communications links such as the Bluetooth® protocol or other wireless personal area network (WPAN) protocols, IEEE 802.11ad protocols, cellular telephone protocols, multiple-input and multiple-output (MIMO) protocols, antenna diversity protocols, satellite navigation system protocols, IEEE 802.15.4 ultra-wideband communications protocols or other ultra-wideband communications protocols, non-Bluetooth protocols for ultra-low-latency audio streaming, etc. Each communications protocol may be associated with a corresponding radio access technology (RAT) that specifies the physical connection methodology used in implementing the protocol.

During operation, wireless circuitry 16 may be used to support communication between device 10 and external equipment 22 (e.g., using radio-frequency signals 24). For example, device 10 and/or external device 22 may transmit video data, application data, audio data, user input commands, and/or other data to each other (e.g., in one or both directions). If desired, device 10 and/or external equipment 22 may use wired and/or wireless communications circuitry to communicate through one or more communications networks (e.g., the internet, local area networks, etc.). If desired, device 10 may communicate with other end hosts over the internet via radio-frequency signals 24 and external equipment 22. Wireless circuitry 16 may allow data to be received by device 10 from external equipment 22 and/or to provide data to external equipment 22.

While controller(s) 20 are shown separately from wireless circuitry 16 for the sake of clarity, wireless circuitry 16 may include processing circuitry and/or storage circuitry that forms part of controller(s) 20 (e.g., portions of controller(s) 20 may be implemented on wireless circuitry 16). As an example, controller(s) 20 may include baseband circuitry (e.g., one or more baseband processors), digital control circuitry, analog control circuitry, and/or other control circuitry that forms part of wireless circuitry 16. The baseband circuitry may, for example, access a communication protocol stack on controller(s) 20 to: perform user plane functions at a PHY layer, MAC layer, RLC layer, PDCP layer, SDAP layer, and/or PDU layer, and/or to perform control plane functions at the PHY layer, MAC layer, RLC layer, PDCP layer, RRC, layer, and/or non-access stratum layer.

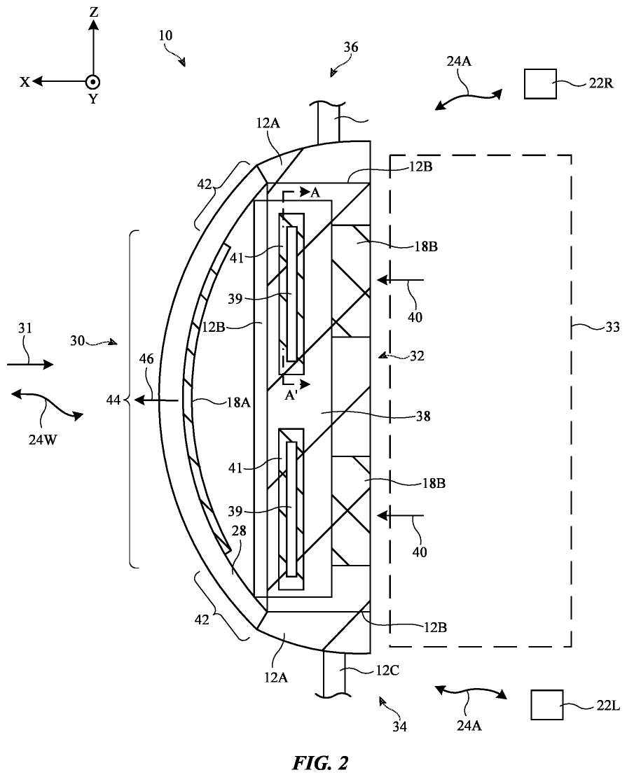

FIG. 2 is a top view of device 10. In the example of FIG. 2, device 10 is a head-mounted device. In general, device 10 may be any suitable electronic equipment. As shown in FIG. 2, device 10 may include housing structures 12. Housing structures 12 may be configured to be worn on a user's head. Housing structures 12 may have curved head-shaped surfaces, a nose-bridge portion that is configured to rest on a user's nose when device 10 is on a user's head, may have a headband such as strap 12C for supporting device 10 on the user's head, and/or may have other features that allow device 10 to be worn by a user.

Housing structures 12 may include one or more frame members such as outer chassis 12A and inner chassis 12B. Outer chassis 12A may be an outer frame surrounding the interior of device 10 and may, if desired, form exterior surfaces of device 10 (e.g., portions of outer chassis 12A may form one or more housing walls of device 10 such as housing walls that run around a periphery of device 10). Inner chassis 12B may be disposed within the interior of device 10 and may be mounted to outer chassis 12A (e.g., outer chassis 12A may surround the lateral periphery of inner chassis 12B in the X-Z plane). Strap 12C may be attached to outer chassis 12A at right side 36 of device 10 and left side 34 of device 10 (e.g., using attachment structures such as a joint, a hinge, screws, fasteners, snaps, magnets, etc.). Strap 12C may be permanently attached to outer chassis 12A or may be removable. Right side 36 may sometimes be referred to herein as right edge 36, right face 36, or right wall 36 of device 10. Left side 34 may extend opposite right side 36 and may sometimes be referred to herein as left edge 34, left face 34, or left wall 34 of device 10. Right side 36 and left side 34 may extend from front side 30 to rear side 32 of device 10.

Outer chassis 12A may be formed from conductive material such as aluminum, stainless steel, or titanium. Outer chassis 12A may therefore sometimes be referred to herein as conductive chassis 12A, conductive outer chassis 12A, outer conductive chassis 12A, conductive outer frame 12A, conductive frame 12A, conductive housing 12A, conductive outer housing 12A, or outer housing 12A. If desired, inner chassis 12B may be formed from a different conductive material than outer chassis 12A (e.g., to meet mounting requirements for the inner chassis, to meet protective requirements for the outer chassis, to meet requirements on mechanical strength and integrity, and minimize device weight). Inner chassis 12B may, for example, be formed from conductive material such as magnesium, aluminum, stainless steel, or titanium. Inner chassis 12B may therefore sometimes be referred to herein as conductive chassis 12B, conductive inner chassis 12B, inner conductive chassis 12B, conductive inner frame 12B, conductive frame 12B, conductive housing 12B, conductive inner housing 12B, inner housing 12B, or conductive support plate 12B.

Outer chassis 12A and inner chassis 12B may provide mechanical support and rigidity for device 10. In addition, one or more components within the interior of device 10 may be mounted or affixed to outer chassis 12A and/or inner chassis 12B. For example, a substrate such as logic board 38 may be mounted to inner chassis 12B. Logic board 38 may, for example, form a main logic board (MLB) for device 10. Other components in device 10 (e.g., portions of I/O components 14 and/or controller(s) 20 of FIG. 1) may be mounted to and/or formed within logic board 38. For example, one or more rear/user facing such as displays 18B may be mounted to logic board 38. Displays 18B may face rear side 32 of device 10. Rear side 32 may sometimes also be referred to herein as rear edge 32, rear wall 32, or rear face 32.

When device 10 is worn on a user's head, the user's head 33 faces rear side 32 of device 10 and the user's eyes are aligned with displays 18B, as shown by arrows 40. Displays 18B may include a left display that aligns with the user's left eye and a right display that aligns with the user's right eye (e.g., the user's left and right eyes may be located within left and right eye boxes of displays 18B). The left and right displays may include respective pixel arrays (or a single shared pixel array) and optics (e.g., one or more lenses) for directing images from the pixel arrays to the user's eyes (e.g., as binocularly fusible content).

The housing structures 12 of device 10 may also include housing structures at the front side 30 of device 10 opposite rear side 32. Front side 30 may sometimes also be referred to herein as front edge 30, front wall 30, or front face 30 of device 10. Housing structures 12 may include a cover glass assembly (CGA) 28 mounted to outer chassis 12A at front side 30 of device 10. CGA 28 may sometimes also be referred to herein as cover 28, front cover 28, or dielectric cover 28 of device 10. CGA 28 may be fully or partially transparent.

CGA 28 may include multiple layers (sometimes referred to herein as cover layers). For example, CGA 28 may include an outer cover layer for device 10 such as a glass cover layer (sometimes referred to herein as a display cover layer or a cover glass). The glass cover layer may form the exterior surface of device 10 at front side 30. CGA 28 may also include one or more dielectric layers behind and overlapping the glass cover layer (e.g., at an interior side of the glass cover layer). The dielectric layer(s) may include one or more polymer layers, plastic layers, glass layers, ceramic layers, and/or other dielectric layers. If desired, some or all of the dielectric layer(s) may be formed in a ring shape that runs along the periphery of CGA 28 in the X-Z plane and the glass cover layer (e.g., at peripheral edge portions 42 of CGA 28) or may overlap substantially all of the glass cover layer. The dielectric layer(s) behind the glass cover layer may sometimes also be referred to as a cover layer, dielectric member, dielectric cover layer, shroud, trim, and/or canopy. Peripheral edge portions 42 may sometimes also be referred to herein as peripheral region 42 or edge region 42.

CGA 28 may also include a forward-facing display such as display 18A (e.g., a flexible display panel formed from a pixel array based on organic light-emitting diodes or other display panel). CGA 28 may have a central portion or region 44 that overlaps display 18A. Peripheral edge portions 42 of CGA 28 may extend around the lateral periphery of CGA 28 and central region 44. Display 18A may emit light (e.g., images) through central region 44 of the dielectric layer(s) and the glass cover layer of CGA 28 (as shown by arrow 46) for view by persons other than the wearer of device 10. The central region 44 of the glass cover layer and the dielectric layer(s) of CGA 28 that overlap display 18A may be fully transparent or partly transparent to help hide display 18A from view when the display is not emitting light. The peripheral edge regions 42 of the glass cover layer and the dielectric layer(s) of CGA 28 may be opaque or transparent. Display 18A may sometimes be referred to herein as a front-facing display, a world-facing display, or a publicly viewable display.

Housing structures 12 may also include cosmetic covering members, polymer layers (e.g., fully or partly transparent polymer layers), and/or dielectric housing walls layered onto or over outer chassis 12A (e.g., at the exterior of device 10) if desired. Housing structures 12 may also include one or more fabric members, rubber members, ceramic members, dielectric members, curtain members, or other structures at rear side 32 of device 10 that help to accommodate the user's face while wearing device 10 and/or to block external, ambient, or scene light from the environment around the user from interfering with or washing out the light from displays 18B being viewed by the user.

Some or all of the lateral surface of CGA 28 may exhibit a curved cross-sectional profile. Within CGA 28, some or all of one or more lateral surfaces of the glass cover layer and/or some or all of one or more of the lateral surfaces of the dielectric layer(s) in CGA 28 may be characterized by a three-dimensional curvature (e.g., spherical curvature, aspherical curvature, freeform curvature, etc.). The three-dimensional curvature may be a compound curvature (e.g., the surfaces exhibiting the curvature may be non-developable surfaces).

In the areas of compound curvature, at least some portions of the curved surface(s) in CGA 28 may be characterized by a radius of curvature R of 4 mm to 250 mm, 8 mm to 200 mm, 10 mm to 150 mm, at least 5 mm, at least 12 mm, at least 16 mm, at least 20 mm, at least 30 mm, less than 200 mm, less than 100 mm, less than 75 mm, less than 55 mm, less than 35 mm, and/or other suitable amount of curvatures. The compound curvature may be, for example, a three-dimensional curvature in which the surface(s) have non-zero radii of curvature about two or more different axes (e.g., non-parallel axes, intersecting axes, non-intersecting axes, perpendicular axes such as the X-axis and Z-axis, etc.) and/or two or more different points within or behind device 10. If desired, one or more of the surfaces of the dielectric layer(s) in CGA 28 may be a developable surface. Display 18A may be a flexible display panel that is bent into a curved shape (e.g., a curved shape following the curved face of a user, a curved shape following the compound curvature of CGA 28, a curved shape characterized by inner and outer developable surfaces, etc.). The compound curvature may serve to provide device 10 with an attractive cosmetic appearance, may help device 10 to exhibit a compact and light weight form factor, may serve to maximize the mechanical strength of device 10, and/or may accommodate easy interaction with device 10 by the user, as examples.

During operation, device 10 may receive image data (e.g., image data for video, still images, etc.) and may present this information on displays 18B and/or 18A. Device 10 may also receive other data, control commands, user input, etc. Device 10 may also transmit data to accessories and other electronic equipment (e.g., external equipment 22 of FIG. 1). For example, image data from a forward-facing camera may be provided to an associated device, audio output may be provided to a device with speakers such as a headphone device, user input and sensor readings may be transmitted to remote equipment, etc.

Communications such as these may be supported using wired and/or wireless communications. In an illustrative configuration, wireless circuitry 16 (FIG. 1) may support wireless communications between device 10 and remote wireless equipment such as external equipment 22 of FIG. 1 (e.g., a cellular telephone, a wireless base station, a computer, headphones or other accessories, a remote control, peer devices, internet servers, and/or other equipment). Wireless communications may be supported using one or more antennas in device 10 and in the external equipment operating at one or more wireless communications frequencies. The antennas may be coupled to wireless transceiver circuitry. The wireless transceiver circuitry may include transmitter circuitry configured to transmit wireless communications signals using the antenna(s) and receiver circuitry configured to receive wireless communications signals using the antenna(s).

External equipment 22 of FIG. 1 may include at least a first accessory or peripheral device 22L and a second accessory or peripheral device 22R, as shown in the example of FIG. 2. Peripheral devices 22R and 22L may, for example, be control input devices (e.g., remote controls, gaming controllers, etc.) or audio output devices such as right and left speakers, right and left speakers of headphones worn by the user, etc. In implementations that are described herein as an example, peripheral device 22R is a right earbud and peripheral device 22L is a left earbud. Peripheral device 22R may therefore sometimes be referred to herein as right earbud 22R and peripheral device 22L may sometimes be referred to herein as left earbud 22L.

While operating device 10, the user wears device 10 on head 33. At the same time, the user wears left earbud 22L on and/or within their left ear (at the left side of head 33) and wears right earbud 22R on and/or within their right ear (at the right side of head 33). Earbuds 22L and 22R may each include a speaker, a battery, one or more processors, and wireless circuitry having one or more antennas. Earbuds 22L and 22R may be wireless earbuds having batteries that are rechargeable when earbuds 22L and 22R are plugged into a power adapter, placed on or within a charging dock, or placed within a charging case, for example.

One or more antennas in device 10 may transmit audio data in radio-frequency signals 24A to earbuds 22R and 22L. Earbuds 22L and 22R may play the audio data over the speakers in earbuds 22L and 22R. The audio data may include a first stream of audio data (e.g., left audio data) for playback by left earbud 22L and a second, different, stream of audio data (e.g., right audio data) for playback by right earbud 22R (e.g., to provide the user with stereo, three-dimensional, spatial, and/or surround sound). One or more antennas in device 10 may also convey other wireless data in radio-frequency signals 24W.

Additionally or alternatively, one or both of earbuds 22L and 22R may include one or more sensors that generate sensor data. The sensors may include a microphone, a touch sensor, a force sensor, an orientation sensor (e.g., a gyroscope, inertial measurement unit, motion sensor, etc.), an ambient light sensor, a proximity sensor, a magnetic sensor, a temperature sensor, and/or other sensors. The microphone may generate microphone data (e.g., voice data from the user speaking while wearing the earbuds). The touch sensor may generate touch sensor data and the force sensor may generate force sensor data (e.g., indicative of a user input provided to device 10 via the earbuds, indicative of the earbuds being presently located in the ears of the user, etc.). The ambient light sensor may generate ambient light sensor data (e.g., indicative of the location of device 10 and/or lighting conditions around the user). In general, the sensors may generate any desired sensor data. Earbuds 22L and 22R may transmit the sensor data to one or more antennas in device 10 using radio-frequency signals 24A and/or using radio-frequency signals 24W.

If care is not taken, components in device 10 can produce an excessive amount of heat. Displays 18B may, for example, be high resolution displays (e.g., 4K displays, 8K displays, or higher resolution displays) that consume a relatively high amount of power and therefore produce a relatively high amount of heat. Thermal management may be particularly important in device 10 because device 10 is worn on a user's head during operation, and care should be taken to ensure that device 10 does not become too hot or uncomfortable when worn by the user. Device 10 may include one or more fans such as fans 41 to help dissipate the thermal load of displays 18B and other components in device 10. Fans 41 may be mounted to logic board 38, for example. Device 10 may include a single fan 41 or multiple fans 41 (e.g., respective fans 41 overlapping the left display 18B and the right display 18B in device 10).

The housing for device 10 may include one or more thermal vents that allow fans 41 to circulate air into and out of device 10 (e.g., fans 41 may convey air through the vents). As used herein, the term “convey air” means the transmission (exhaust) and/or reception (intake) of air. For example, outer chassis 12A may include one or more thermal vents 39 aligned with one or more corresponding fans 41. Some vents 39 may be used for the intake of cool air (sometimes referred to herein as thermal intake vents) whereas other vents 39 are used for the exhaust of warm air (sometimes referred to herein as thermal exhaust vents). Vents 39 are sometimes also referred to herein as thermal ports 49 (e.g., intake ports and exhaust ports).

Each fan 41 may, for example, have at least one corresponding intake vent 39 and at least one corresponding exhaust vent 39. When driven, fan blades in fan 41 rotate, drawing cool air into device 10 through the intake vent. The cool air absorbs heat from displays 18B and/or other components on logic board 38 or elsewhere in device 10. The rotating fan blades of fan 41 push the heated air out of device 10 through the exhaust vent.

The intake vent and the exhaust vent may be located on opposing sides of device 10 if desired. This may help to prevent warm air expelled through the exhaust vent from being drawn back into the intake vent instead of cooler air. Disposing the intake vent along the bottom or check side of device 10 and the exhaust vent along the top or brow side of device 10 may, for example, help to prevent warm air output by the exhaust vent from rising towards the intake vent.

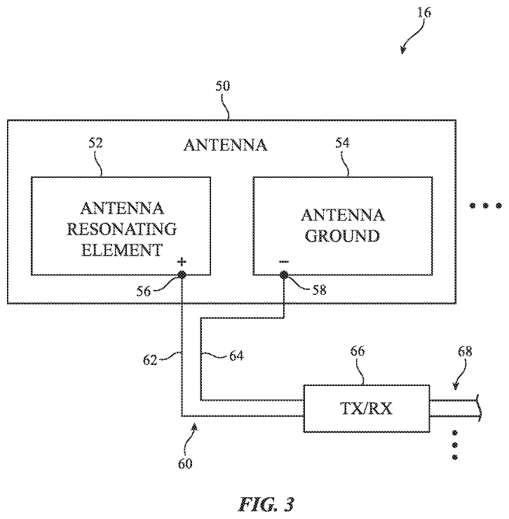

FIG. 3 is a diagram of illustrative components in wireless circuitry 16 of device 10. As shown in FIG. 3, wireless circuitry 16 may include one or more transceivers (e.g., transceiver circuitry) such as transceiver (TX/RX) 66. Transceiver 66 may handle transmission and/or reception of radio-frequency signals 24 (e.g., radio-frequency signals 24A or 24W of FIG. 2) within corresponding frequency bands at radio frequencies (sometimes referred to herein as communications bands or simply as bands).

The frequency bands handled by transceiver 66 may include wireless personal area network (WPAN) frequency bands such as the 2.4 GHz Bluetooth® band or other WPAN communications bands, cellular telephone communications bands such as a cellular low band (600-960 MHz), a cellular low-midband (1400-1550 MHz), a cellular midband (1700-2200 MHz), a cellular high band (2300-2700 MHz), a cellular ultra-high band (3300-5000 MHz), or other cellular communications bands between about 600 MHz and about 5000 MHz), 3G bands, 4G LTE bands, 3GPP 5G New Radio (NR) Frequency Range 1 (FR1) bands below 10 GHz, 3GPP 5G NR Frequency Range 2 (FR2) bands between 20 and 60 GHz, other centimeter or millimeter wave frequency bands between 10-300 GHz, sub-THz or THz bands between around 100-1000 GHz (e.g., 6G bands), wireless local area network (WLAN) frequency bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), near-field communications frequency bands (e.g., at 13.56 MHz), satellite navigation frequency bands such as the Global Positioning System (GPS) bands, Global Navigation Satellite System (GLONASS) bands, and BeiDou Navigation Satellite System (BDS) bands, ultra-wideband (UWB) frequency bands that operate under the IEEE 802.15.4 protocol and/or other ultra-wideband communications protocols (e.g., a first UWB communications band at 6.5 GHz and/or a second UWB communications band at 8.0 GHz), communications bands under the family of 3GPP wireless communications standards, communications bands under the IEEE 802.XX family of standards, satellite communications bands, unlicensed bands such as an unlicensed band at 2.4 GHz and/or an unlicensed band between 5-6 GHz, emergency and/or public services bands, and/or any other desired frequency bands of interest. Transceiver 66 may also be used to perform spatial ranging operations if desired (e.g., using a radar sensing scheme).

As shown in FIG. 3, wireless circuitry 16 may also include one or more antennas 50. Transceiver 66 may convey (e.g., transmit and/or receive) radio-frequency signals 24 using one or more antennas 50. Each antenna 50 may include one or more antenna conductors formed from conductive material such as metal. The antenna conductors may include one or more antenna conductors that form antenna resonating element 52 (sometimes referred to as an antenna resonator, an antenna radiator, or an antenna radiating element) and one or more antenna conductors that form antenna ground 54 (sometimes referred to as a ground plane).

Antenna 50 may have an antenna feed coupled between antenna resonating element 52 and antenna ground 54. The antenna feed may have a first (positive or signal) antenna feed terminal 56 coupled to antenna resonating element 52. The antenna feed may also have a second (ground or negative) antenna feed terminal 58 coupled to antenna ground 54. Antenna resonating element 52 may be separated from antenna ground 54 by a dielectric (non-conductive) gap. Antenna resonating element 52 and antenna ground 54 may be formed from separate pieces of metal or other conductive materials or may, if desired, be formed from separate portions of the same integral piece of metal. If desired, antenna 50 may include additional antenna conductors that are not coupled to antenna feed terminals 56 and 58 (e.g., parasitic elements). For some types of antennas (e.g., in implementations where antenna 50 is a slot antenna), the antenna resonating element may be formed from a slot in a single antenna conductor that is coupled to both antenna feed terminals 56 and 58 (e.g., where antenna feed terminals 56 and 58 are coupled to opposing sides of the slot).

Each antenna feed and thus each antenna 50 in wireless circuitry 16 may be coupled to one or more transceivers 66 in wireless circuitry 16 over a corresponding radio-frequency transmission line 60. Radio-frequency transmission line 60 may include a signal conductor such as signal conductor 62 (e.g., a positive signal conductor) and a ground conductor such as ground conductor 64. Ground conductor 64 may be coupled to antenna feed terminal 58 of antenna 50. Signal conductor 62 may be coupled to antenna feed terminal 56 of antenna 50. Radio-frequency transmission line 60 may include one or more of a stripline, microstrip, coaxial cable, coaxial probes, edge-coupled microstrip, edge-coupled stripline, waveguide, radio-frequency connector, combinations of these, etc. Radio-frequency transmission line 60 may also sometimes be referred to herein as a radio-frequency transmission line path. If desired, filter circuitry, tuning components, switching circuitry, impedance matching circuitry, phase shifter circuitry, amplifier circuitry, and/or other circuitry may be disposed on radio-frequency transmission line 60 and/or may be coupled between two or more of the antenna conductors in antenna 50.

The term “convey radio-frequency signals” as used herein means the transmission and/or reception of the radio-frequency signals (e.g., for performing unidirectional and/or bidirectional wireless communications with external wireless communications equipment). During transmission of radio-frequency signals 24, transceiver 66 transmits radio-frequency signals 24 (e.g., as modulated using wireless data such as audio data, control data, etc.) over radio-frequency transmission line 60. The radio-frequency signals may excite antenna currents to flow around the edges of antenna resonating element 52 and antenna ground 54 (via antenna feed terminals 56 and 58). The antenna currents may radiate radio-frequency signals 24 into free space (e.g., based at least on a resonance established by the radiating length of antenna resonating element 52 and/or antenna ground 54).

During the reception of radio-frequency signals 24 (e.g., as modulated by external equipment using wireless data such as voice data, sensor data, image data, etc.), incident radio-frequency signals 24 may excite antenna currents to flow around the edges of antenna resonating element 52 and antenna ground 54. The antenna currents may pass radio-frequency signals 24 to transceiver 66 over radio-frequency transmission line 60. Transceiver 66 may downconvert the radio-frequency signals to baseband and may demodulate wireless data from the signals (e.g., using baseband circuitry such as one or more baseband processors).

Antennas 50 may be formed using any suitable antenna structures. For example, antennas 50 may include antennas with antenna resonating elements that are formed from patch antenna structures (e.g., shorted patch antenna structures), slot antenna structures, loop antenna structures, stacked patch antenna structures, antenna structures having parasitic elements, inverted-F antenna structures, planar inverted-F antenna structures, helical antenna structures, monopole antenna structures, dipole antenna structures, Yagi (Yagi-Uda) antenna structures, surface integrated waveguide structures, hybrids of two or more of these designs, etc. If desired, one or more antennas 50 may be cavity-backed antennas. Antenna 50 may include one or more antenna conductors that form a parasitic antenna resonating element. Whereas antenna resonating element 52 is directly fed (e.g., via positive antenna feed terminal 56), parasitic antenna resonating elements are not directly fed (e.g., are indirectly fed by antenna resonating element 52) and/or serve to modify the radiation pattern and/or radiative characteristics of antenna 50. Two or more antennas 50 may be arranged in a phased antenna array if desired (e.g., for conveying centimeter and/or millimeter wave signals within a signal beam formed in a desired beam pointing direction that may be steered/adjusted over time). Earbuds 22R and 22L may also have wireless circuitry such as wireless circuitry 16 of FIG. 3.

Device 10 may include a first set of one or more antennas that convey radio-frequency signals 24A with earbuds 22R and 22L (FIG. 2). Device 10 may also include a second set of one or more antennas that convey radio-frequency signals 24W with other external equipment 22. Radio-frequency signals 24A may, for example, be conveyed through or towards rear side 32 of device 10, as shown in FIG. 2 (e.g., to and from the expected location of earbuds 22L and 22R while the user wears device 10). Radio-frequency signals 24W may be conveyed through front side 30 of device 10, through rear side 32, and/or through other sides of device 10. Radio-frequency signals 24A may be conveyed using a first radio access technology (RAT), a first communications protocol, a first transceiver in device 10, and/or a first set of frequencies or frequency bands. Radio-frequency signals 24W may be conveyed using a second RAT different from the first RAT, a second communications protocol different from the first communications protocol, a second transceiver in device 10 different from the first transceiver, and/or a second set of frequencies or frequency bands different from the first set of frequencies or frequency bands.

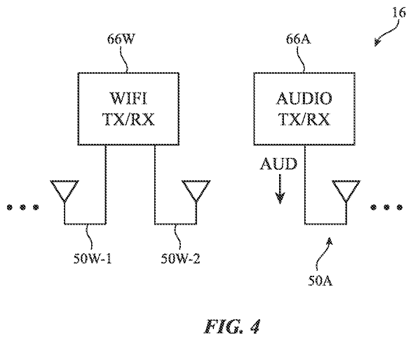

FIG. 4 is a diagram showing how wireless circuitry 16 may include different components for conveying radio-frequency signals 24A and 24W. As shown in FIG. 4, wireless circuitry 16 may use at least one antenna 50A to convey radio-frequency signals 24A and may use at least two antennas 50W (e.g., at least a first antenna 50W-1 and a second antenna 50W-2) to convey radio-frequency signals 24W (FIG. 2). While radio-frequency signals 24A may, in general, convey any desired wireless data between device 10 and multiple peripheral devices, an implementation in which radio-frequency signals 24A convey audio data and sensor data between device 10 and earbuds 22L and 22R is described herein as an example.

Antennas 50W-1 and 50W-2 may be coupled to a first transceiver 66W over respective radio-frequency transmission lines. Antenna 50A may be coupled to a second transceiver 66A over a corresponding radio-frequency transmission line. Transceivers 66W and 66A may be formed using different respective radios, modems, chips, integrated circuits, integrated circuit (IC) packages, and/or modules. Transceiver 66W may convey radio-frequency signals 24W (FIG. 2) with external equipment other than earbuds 22R and 22L and/or with earbuds 22R and 22L using antennas 50W-1 and 50W-2. Transceiver 66W may, for example, have respective first and second transmit chains and respective first and second receive chains (e.g., respective first and second ports) coupled to antennas 50W-1 and 50W-2.

Transceiver 66W may convey radio-frequency signals 24W using at least a first communications protocol, at least a first RAT, and a first set of frequency bands. An implementation in which radio-frequency signals 24W include WLAN signals conveyed using a WLAN protocol (e.g., a Wi-Fi protocol), the WLAN RAT, and WLAN frequency bands is described herein as an example. If desired, radio-frequency signals 24W may also include Bluetooth signals conveyed using a Bluetooth protocol and Bluetooth frequency bands. Transceiver 66W may therefore sometimes be referred to herein as WLAN transceiver 66W, Wi-Fi transceiver 66W, or WLAN/Bluetooth transceiver 66W. Radio-frequency signals 24W may sometimes be referred to herein as WLAN or Wi-Fi signals 24W. This is merely illustrative and, in general, radio-frequency signals 24W may be conveyed using any desired protocol(s).

In some scenarios, Bluetooth signals conveyed by transceiver 66W are used to convey streams of audio data between device 10 and earbuds 22L and 22R. However, Bluetooth signaling can involve an excessive amount of latency and an excessive glitch rate. This can be disruptive to the user experience while listening to audio on earbuds 22L and 22R, particularly for audio data with a relatively high data rate (e.g., as may be required for immersive, high definition, three-dimensional audio presented to the user along with virtual reality content on displays 18B of FIG. 2). The high latency and excessive glitch rate associated with Bluetooth signaling may be caused by the Bluetooth protocol's requirement for time division duplexing between earbuds 22L and 22R (e.g., where audio data packets are transmitted to right earbud 22R and then to left earbud 22L in a time-alternating manner), frequency hopping between different Bluetooth frequencies, and a relatively large tolerance for packet retransmissions, for example.

To mitigate these issues, transceiver 66A may convey radio-frequency signals 24A (FIG. 2) using a second communications protocol, a second RAT, and a second set of frequency bands different from those used by transceiver 66W. For example, transceiver 66A may convey radio-frequency signals 24A using a non-Bluetooth, ultra-low-latency audio (ULLA) communications protocol optimized to support low latency and high data rate audio streaming from device 10 to earbuds 22L and 22R. Radio-frequency signals 24A may be conveyed in different frequency bands than radio-frequency signals 24W. For example, radio-frequency signals 24A may be conveyed using an unlicensed band at 2.4 GHz and/or an unlicensed band between 5-6 GHz. The band between 5-6 GHz may allow for a larger bandwidth than the 2.4 GHz band. In addition, the band between 5-6 GHz may allow for fewer coexistence/interference issues than the 2.4 GHz band, which coexists with the Bluetooth band, household appliances such as microwaves that emit around 2.4 GHz, etc.

The ultra-low-latency audio protocol may involve communications without performing time division duplexing between earbuds 22L and 22R and may involve communications with a lower packet re-transmission count limit, lower latency, lower glitch rate (e.g., 1 glitch per hour or fewer), more stability, and less interference than the Bluetooth protocol. Further, the ultra-low-latency audio protocol requires both earbuds 22R and 22L to convey radio-frequency signals 24A directly with device 10 rather than relaying signals or data between earbuds 22R and 2L and has a wireless fading channel selected to have a tighter distribution and shorter tail at the low power end than the Bluetooth protocol. Transceiver 66A may therefore sometimes be referred to herein as audio transceiver 66A. Radio-frequency signals 24A may sometimes be referred to herein as audio signals 24A. The example in which transceiver 66A conveys audio data is merely illustrative and, in general, transceiver 66A may use radio-frequency signals 24A to convey any desired wireless data.

During transmission, transceiver 66A may transmit audio data AUD in radio-frequency signals 24A (e.g., radio-frequency signals 24A may be modulated to carry audio data AUD). Antenna 50A may transmit the radio-frequency signals 24A including audio data AUD. Audio data AUD may include a stream of audio data packets. The stream of audio data packets may include a first set of audio data packets (or any desired first portion of the stream of audio data as distributed across one or more packets) for playback by left earbud 22L (e.g., a stream of left speaker audio data). The stream of audio data packets may also include a second set of audio data packets (or any desired second portion of the stream of audio data as distributed across one or more packets) for playback by right earbud 22R (e.g., a stream of right speaker audio data). The first and second sets may be interspersed or interleaved in time, for example.

Since the ultra-low-latency audio communications protocol governing transmission of radio-frequency signals 24A does not involve time division duplexing (TDD) between earbuds 22R and 22L, the same audio data AUD (e.g., the stream of audio data packets including both left and right speaker audio data) is concurrently (e.g., simultaneously) transmitted to both earbuds 22R and 22L and is concurrently received by both earbuds 22R and 22L. The controllers on earbuds 22R and 22L may demodulate the received audio data to recover the first and second sets of audio data packets. Left earbud 22L may then play the first set of audio data packets without playing (e.g., while discarding) the received second set of audio data packets. Right earbud 22R may play the second set of audio data packets without playing (e.g., while discarding) the received first set of audio data packets. Earbuds 22L and 22R may also transmit radio-frequency signals 24A to antenna 50A on device 10 to confirm/acknowledge receipt of audio data AUD, to convey voice/sensor data to device 10, etc. Since the sensor data gathered by earbuds 22R and 22L may not be subject to the same strict latency requirements as the audio data conveyed by transceiver 66A, earbuds 22L and 22R may, if desired, include additional wireless circuitry that transmits some or all of the sensor data to device 10 using the Bluetooth protocol or other protocols.

In some situations, using the same antenna 50A to convey radio-frequency signals 24A with both earbuds 22R and 22L can cause an excessive glitch rate due to random transmission nulls and the fading channel between antenna 50A and the earbuds. To improve link quality and glitch rate, wireless circuitry 16 may include different respective antennas 50A for conveying radio-frequency signals 24A with earbuds 22R and 22L, if desired.

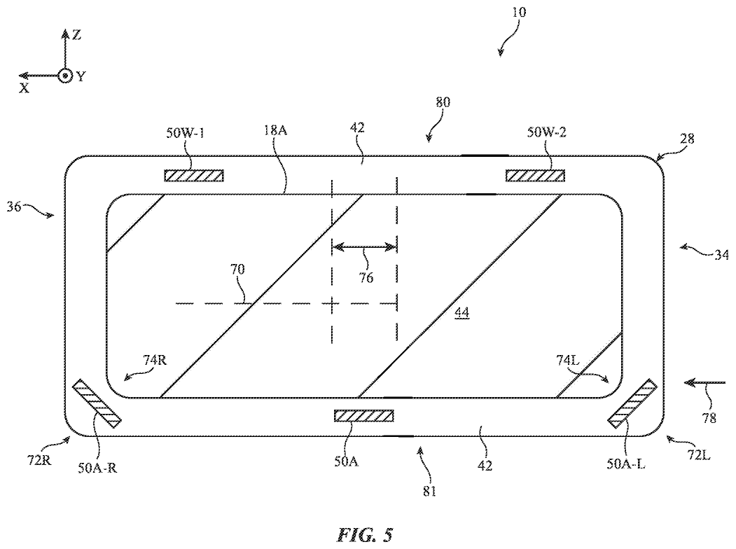

Given the compact and lightweight form factor of device 10 and the presence of conductive structures in device 10 such as outer chassis 12A, inner chassis 12B, conductive portions of logic board 38, displays 18B, and display 18A, it can be challenging to place antennas 50 at locations device 10 that allow the antennas to exhibit satisfactory levels of radio-frequency performance. To help maximize the wireless performance of antennas 50, antennas 50 may be mounted at the front of device 10 and may overlap peripheral edge portions 42 of CGA 28. FIG. 5 is a front view of device 10 (e.g., as viewed in the direction of arrow 31 of FIG. 2) showing how antennas 50 may be mounted at the front of device 10 and overlapping peripheral edge portions 42 of CGA 28.

As shown in FIG. 5, the front-facing display 18A on device 10 may overlap central region 44 of CGA 28 but not peripheral edge portions 42 of CGA 28. Display 18A (central region 44) may be laterally surrounded by peripheral edge portions 42 of CGA 28. In other words, peripheral edge portions 42 may extend around the lateral periphery of display 18A (e.g., when viewed in the X-Z plane). Peripheral edge portions 42 may, for example, form an inactive (conductor-free) portion of CGA 28 that extends around or along the lateral periphery of CGA 28, central region 44 of CGA 28, and display 18A.

Device 10 may have a top side 80 and a bottom side 81 opposite top side 80. Top side 80 may sometimes also be referred to herein as top edge 80, top wall 80, or top face 80 of device 10. Bottom side 81 may sometimes also be referred to herein as bottom edge 81, bottom wall 81, or bottom face 81 of device 10. Right side 36 and left side 34 may extend from top side 80 to bottom side 81 of device 10.

Device 10 may have corners 72 such as a bottom-right corner 72R where right side 36 meets bottom side 81 and a bottom-left corner 72L where left side 34 meets bottom side 81. Display 18A may have corners 74 such as a bottom-right corner 74R facing corner 72R of device 10 and a bottom-left corner 74L facing corner 74L of device 10.

The housing structures of device 10 may have a nose bridge portion such as nose bridge region 85. Nose bridge region 85 may rest on the user's nose while wearing device 10 on their head. Nose bridge region 85 may be laterally interposed between the left and right displays 18B in device 10 (FIG. 2), for example. Nose bridge region 85 may vertically extend from top side 80 to bottom side 81 at the center of device 10.

Display 18A may include pixel circuitry and other conductive components that can block radio-frequency signals conveyed by the antennas in device 10. As such, antennas 50W-1, 50W-2, and one or more antennas 50A may be disposed within device 10 at locations overlapping peripheral edge portions 42 of CGA 28. As shown in FIG. 5, antennas 50W-1 and 50W-2 may be mounted within device 10 and overlapping an upper region or area of peripheral edge portions 42 (e.g., antennas 50W-1 and 50W-2 may be interposed between display 18A and top side 80 of device 10).

Antennas 50W-1 and 50W-2 may convey radio-frequency signals 24W through the dielectric material in CGA 28 and/or the top, bottom, right, left, and/or rear sides of device 10. Antennas 50W-1 and 50W-2 may be disposed at opposing sides of device 10 (e.g., antenna 50W-1 may be disposed at or adjacent right side 36 whereas antenna 50W-2 is disposed at or adjacent left side 34 of device 10) to maximize spatial diversity for transceiver 66W. Antennas 50W-1 and 50W-2 may, for example, be mounted at opposing sides of nose bridge region 85.

The antennas 50A in device 10 may be mounted within device 10 and overlapping a lower region or area of peripheral edge portions 42 (e.g., antenna(s) 50A may be interposed between display 18A and bottom side 81 of device 10). Disposing antenna(s) 50A along the bottom edge of device 10 may serve to minimize the amount of conductive material in device 10 that lies between antenna(s) 50A and the location of earbuds 22R and 22L (FIG. 2) while device 10 is being worn by the user.

In implementations where device 10 includes a single antenna 50A, antenna 50A may convey radio-frequency signals 24A with both earbuds 22R and 22L (FIG. 2) through the dielectric material in CGA 28 and/or the top, bottom, right, left, and/or rear sides of device 10. Antenna 50A may be mounted at or adjacent the center of device 10. For example, antenna 50A may overlap nose bridge portion 85 of device 10 (e.g., antenna 50A may be disposed at the center of device 10 along the X-axis). This may allow antenna 50A to exhibit optimal and balanced channel conditions with both right earbud 22R at right side 36 of device 10 and left earbud 22L at left side 34 of device 10.

In implementations where device 10 includes multiple antennas 50A such as at least a first antenna 50A-L and a second antenna 50A-R, antenna 50A-R may be mounted at or adjacent to corner 74R of display 18A and/or corner 72R of device 10 (e.g., antenna 50A-R may be laterally interposed between corner 74R of display 18A and corner 72R of device 10). Antenna 50A-L may be mounted at or adjacent to corner 74L of display 18A and/or corner 72L of device 10 (e.g., antenna 50A-L may be laterally interposed between corner 74L of display 18A and corner 72L of device 10). In this way, display 18A may be vertically interposed between the antennas 50W (FIG. 9) and the antenna(s) 50A in device 10, thereby maximizing physical separation and thus isolation between antennas 50W and antenna(s) 50A.

Device 10 may have a central longitudinal axis 70 extending from right side 36 to left side 34 (parallel to the X-axis and perpendicular to nose bridge region 85 of FIG. 9). If desired, antennas 50A-L and 50A-R (e.g., the lateral surfaces of antenna resonating elements 52 (FIG. 3) in antennas 50A-L and 50A-R) may be tilted at non-parallel and non-perpendicular angles with respect to longitudinal axis 70. When placed and oriented in this way, antenna 50A-R may exhibit optimal channel characteristics in conveying radio-frequency signals 24A-R with right earbud 22R (e.g., with minimal blockage by the user's head, display 18A, and/or the other conductive structures of device 10). Similarly, antenna 50A-L may exhibit optimal channel characteristics in conveying radio-frequency signals 24A-R with left earbud 22L (e.g., with minimal blockage by the user's head, display 18A, and/or the other conductive structures of device 10).

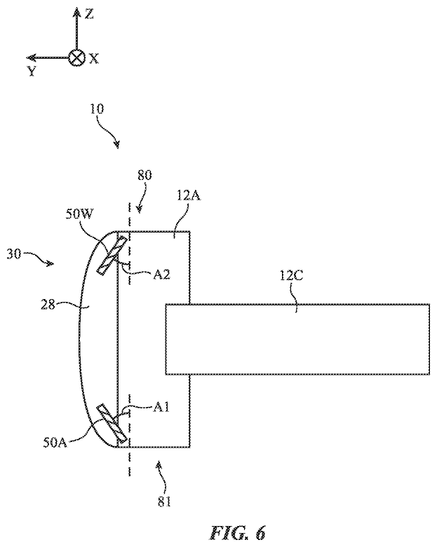

The example of FIG. 5 in which antennas 50W and 50A are mounted in device 10 at locations overlapping CGA 28 are merely illustrative. If desired, antennas 50W and/or 50A may be disposed within strap 12C of device 10 and/or at rear side 32 of device 10 (FIG. 2). FIG. 6 is a side view (e.g., taken in the direction of arrow 78 of FIG. 5) showing how antennas 50W and 50A may be disposed at front side 30 of device 10.

As shown in FIG. 6, an antenna 50W (e.g., antenna 50W-1 and/or antenna 50W-2 of FIG. 5) may be mounted at or adjacent to front side 30 and top side 80 of device 10. An antenna 50A (e.g., antenna 50A, antenna 50A-R, and/or antenna 50A-L of FIG. 5) may be mounted at or adjacent to front side 30 and bottom side 81 of device 10. Antenna 50W and antenna 50A may be pressed against, mounted to, mounted (e.g., embedded) within, printed on, adhered to, affixed to, or mounted adjacent to CGA 28.

Antenna 50W may be tilted, rotated, or oriented at a non-parallel and non-perpendicular angle A2 with respect to longitudinal axis 70 (FIG. 5), the rear side of device 10, and/or the X-Z plane. Angle A2 may be 45 degrees, 30-60 degrees, 1-30 degrees, 1-45 degrees, 5-35 degrees, or other angles. Similarly, antenna 50A may be tilted, rotated, or oriented at a non-parallel and non-perpendicular angle A1 with respect to longitudinal axis 70 (FIG. 5), the rear side of device 10, and/or the X-Z plane. Angle A1 may be 45 degrees, 30-60 degrees, 1-30 degrees, 1-45 degrees, 5-35 degrees, or other angles. Angle A1 may be equal to angle A2 or may be different from angle A2.

If desired, the lateral surface of the antenna resonating elements 52 (FIG. 3) in antennas 50W and 50A may extend parallel to the curved surface(s) of CGA 28 (e.g., the antenna resonating elements may exhibit the same compound curvature as CGA 28). This may serve to provide a uniform separation between all points on the lateral surface of the antenna resonating elements and the overlapping portions of CGA 28, which minimizes antenna impedance mismatch across the antenna resonating elements and thus maximizes antenna efficiency.

When placed and oriented in this way, antenna(s) 50A may exhibit optimal channel characteristics in conveying radio-frequency signals 24A with right earbud 22R and left ear bud 22L (e.g., with minimal blockage by the user's head, display 18A, and/or the other conductive structures of device 10). Mounting the antennas at the rear side of device 10 may subject the antennas to undesirable detuning when displays 18B (FIG. 2) move over time and/or due to impedance loading from the user's head. Mounting the antennas at front side 30 of device 10 (as shown in FIGS. 5 and 6) may minimize the impact of displays 18B (FIG. 2) on the antennas (e.g., such that movement of displays 18B does not detune the antennas). In addition, mounting the antennas at front side 30 of device 10 may minimize fading channel path loss, may minimize user-to-user variation in the impedance loading of the antennas by the user's head, and may minimize and the amount of radio-frequency energy exposure produced by the antennas on the user's body, helping device 10 to comply with regulatory limits on radio-frequency energy exposure or absorption (e.g., without requiring transmit power level backoffs for the antenna) while meeting the strict latency and glitch rate requirements of the ultra-low-latency audio communications protocol.

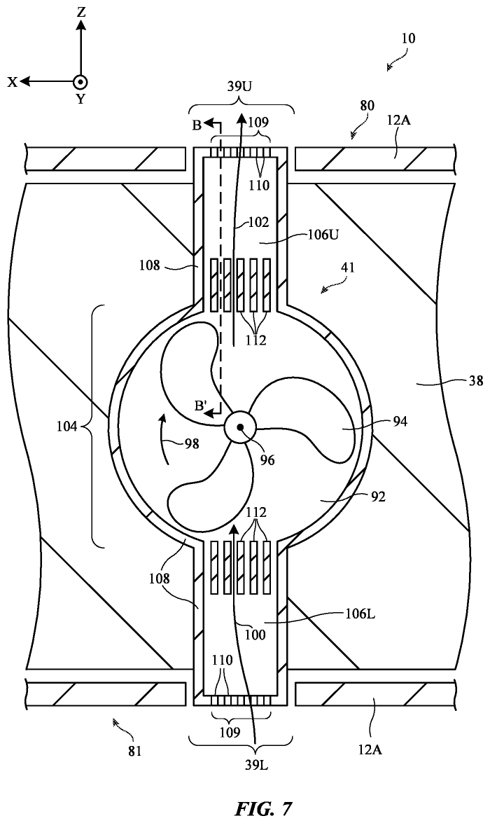

FIG. 7 is a cross-sectional front view of a given fan 41 in device 10 (e.g., as taken along line AA′ of FIG. 2). In the example of FIG. 7, CGA 28, inner chassis 12B, and displays 18B of FIG. 2 have been omitted for the sake of clarity.

As shown in FIG. 7, fan 41 may include a fan cavity 92 (sometimes also referred to herein as fan volume 92). Fan 41 may have a fan housing 108 (sometimes also referred to herein as fan bracket 108). Fan housing 108 has housing walls that surround and enclose fan cavity 92 (e.g., the housing walls of fan housing 108 define the edges or boundaries of fan cavity 92). Fan housing 108 may be mounted to an underlying or overlying substrate such as logic board 38.

Fan cavity 92 may include a central portion such as central portion 104 (sometimes also referred herein as central volume 104). Fan cavity 92 may also include elongated portions such as one or more tunnels 106. Tunnels 106 are sometimes also referred to herein as ventilation tunnels 106, ventilation shafts 106, shafts 106, or (elongated) segments/portions 106 of fan cavity 92. The overall volume of fan cavity 92 is given by the sum of the volume of central portion 104 and the volume of each tunnel 106 in fan 41.

Each tunnel 106 extends from central portion 104 to a respective vent 39 in outer chassis 12A. For example, as shown in FIG. 7, fan 41 may include a first tunnel 106U extending from a first (upper) side/edge of central portion 104 to a corresponding vent 39U in outer chassis 12A (e.g., at top side 80 of device 10). Fan 41 may also include a second tunnel 106U extending from an opposing second (lower) side/edge of central portion 104 to a corresponding vent 39L in outer chassis 12A (e.g., at bottom side 81 of device 10).

Fan housing 108 may include a respective port 109 (sometimes also referred to herein as opening 109) aligned with each of vents 39U and 39L. Fan 41 may include a breathable protective covering such as covering 110 disposed within each port 109 (e.g., between opposing walls of fan housing 108). Covering 110 may, for example, be formed from fabric, mesh, or other materials having openings that allow air to pass through the corresponding port 109 but that otherwise minimize or prevent the ingress of moisture, dust, and/or other contaminants into the interior of device 10.

Fan 41 may include fan blades 94 disposed in central portion 104 of fan cavity 92. Tunnels 106U and 106L are free from fan blades (e.g., fan blades 94 do not extend into tunnels 106U and 106L). Fan blades 94 may be formed from metal, plastic, or metal-plated plastic, as examples. Controller(s) 20 (FIG. 1) may provide electrical signals that drive fan blades 94 to rotate about axis 96, as shown by arrow 98. The electrical signals may be adjusted to adjust the rotational speed of fan blades 94. When fan blades 94 rotate around axis 96, fan blades 94 draw or suck air into central portion 104 of fan cavity 92 through vent 39L and tunnel 106L, as shown by arrow 100. The air drawn into tunnel 106L is relatively cool. Fan blades 94 may circulate this air within central portion 104 of fan cavity 92, causing the air to warm as the air absorbs heat from other components on logic board 38 such as displays 18B (FIG. 2).

As fan blades 94 rotate, the fan blades also push, expel, or exhaust the warmed (heated) air from central portion 104 out of fan cavity 92 through tunnel 106L and vent 39U, as shown by arrow 102. The warmed air exhausted through vent 39U removes heat from the interior of device 10, thereby helping to cool and mitigate thermal load in device 10. Vent 39U is sometimes also referred to herein as exhaust vent 39U. Tunnel 106U is sometimes also referred to herein as exhaust tunnel 106U. Tunnel 106L is sometimes also referred to herein as intake tunnel 106L. Vent 39L is sometimes also referred to herein as intake vent 106L. Vents 39U and 39L are sometimes also referred to herein collectively as cooling vents or (air) circulation vents.

Fan 41 may include one or more fins 112 within fan cavity 92. Fins 112 may be located within tunnel 106U (e.g., where tunnel 106U meets central portion 104), within tunnel 106L (e.g., where tunnel 106L meets central portion 104), within central cavity 104 (not shown), and/or elsewhere in fan cavity 92. Fins 112 may be separated from each other and/or the walls of fan housing 108 by air flow channels or passages within fan cavity 92 and may help to guide air flow within fan cavity 92 (e.g., as shown by arrows 100 and 102). Additionally or alternatively, fins 112 may help to perform thermal dissipation within device 10 (e.g., for logic board 38). Fins 112 may, for example, be formed from metal and/or other thermally-conductive materials that help to transfer heat from logic board 38 (or components mounted to logic board 38, components within device 10 but not mounted to logic board 38, etc.) into the air that circulates within fan cavity 92. Fins 112 may sometimes also be referred to herein as thermal dissipation fins or airflow guiding fins.

Central portion 104 of fan cavity 92 may be wider (e.g., may have greater volume) than tunnels 106U and 106L (e.g., to accommodate fan blades 94). Tunnels 106U and 106L may be relatively narrow to help guide air flow within device 10 (e.g., with sufficient velocity) and/or to accommodate the presence of other components on logic board 38 and/or within device 10 (e.g., given the small form factor of device 10).

The example of FIG. 7 is merely illustrative. If desired, fan 41 may draw cool air through vent 39U and may exhaust warm air through vent 39L (e.g., vent 39L may be an exhaust vent whereas vent 39U may be an intake vent). Vents 39U and 39L may be located elsewhere in device 10. Tunnels 106U and 106L may follow linear paths, curved paths, non-linear paths, and/or any other desired paths having any desired number of linear and/or curved segments extending in any desired directions. Fan housing 108 may have other shapes. Fan 41 may include any desired number of fan blades 94. Fins 112 may have other shapes, may have other orientations, be located elsewhere within fan cavity 92, or may be omitted. There may be any desired number of fins 112 in fan cavity 92. If desired, the tunnels 106 of fan 41 may guide cool air into fan cavity 92 and may guide warm air out of fan cavity 92 through the same vent 39 in outer chassis 12A. If desired, fan 41 may include more than two tunnels 106 extending to more than two vents 39.

Some or all of the housing walls of fan housing 108 may be formed from metal. Forming fan housing 108 from metal may, for example, help to maximize the mechanical strength of device 10 (e.g., preventing damage from drop events, twisting forces, etc.), maximize the mechanical strength of fan 41 (e.g., to minimize wear to the fan over time), increase thermal dissipation in device 10 (e.g., by facilitating heat transfer from outside fan housing 108 onto the air circulating within fan cavity 92), etc.

In practice, it may be desirable for fan 41 to be as large as possible to maximize cooling. However, if care is not taken, the presence of metal in fan housing 108 can limit the volume of one or more of the antennas 50 disposed at or on CGA 28 (FIGS. 5 and 6). Limiting the volume of an antenna 50 (e.g., the volume between the antenna resonating element 52 and the antenna ground 54 of the antenna (FIG. 3)) limits its efficiency bandwidth and increases device-to-device variation in antenna performance. To mitigate these issues, at least part of a given antenna 50 may be integrated into fan 41 (e.g., to maximize antenna performance while also maximizing cooling for device 10).

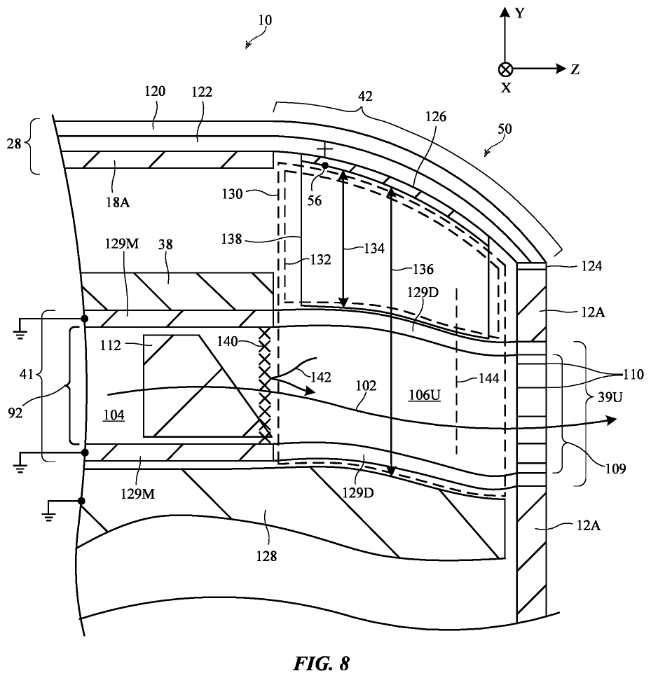

FIG. 8 is a cross-sectional side view showing one example of how antenna 50 may be integrated into fan 41 (e.g., at the upper side of device 10, as taken in the direction of line BB′ of FIG. 7). The structures of FIG. 8 may additionally or alternatively be implemented at the bottom side of device 10 (e.g., extending from central portion 104 of fan cavity 92 to vent 39L of FIG. 7).

As shown in FIG. 8, CGA 28 may include an outermost layer such as cover glass layer 120. If desired, CGA 28 may also include a dielectric cover layer such as dielectric layer 122 on, at, or adjacent to the interior side of cover glass layer 120. While CGA 28 may have multiple dielectric layers 122 stacked under cover glass layer 120, a single dielectric layer 122 is shown in FIG. 8 for the sake of clarity.

In the example of FIG. 8, dielectric layer 122 is shown as being layered onto (e.g., adhered or molded onto) the inner surface of cover glass layer 120 for the sake of clarity. However, if desired, some or all of the lateral area of dielectric layer 122 may be separated from cover glass layer 120 by an air gap (not shown) and/or one or more intervening structures or layers (not shown). The outer lateral surface of dielectric layer 122 may have the same curvature as cover glass layer 120 or a different curvature and the inner lateral surface of dielectric layer 122 may have the same curvature as cover glass layer 120 or a different curvature. The outer lateral surface of dielectric layer 122 may have the same curvature as the inner lateral surface of dielectric layer 122 (e.g., the inner and outer lateral surfaces may extend parallel to each other) or the outer lateral surface of dielectric layer 122 may have a different curvature than the inner lateral surface of dielectric layer 122 (e.g., the inner and outer lateral surfaces may be non-parallel).

Cover glass layer 120 may be formed from glass, sapphire, or other transparent materials. Cover glass layer 120 may be replaced with an outermost plastic cover layer if desired. Cover glass layer 120 may sometimes be referred to herein as cover layer 120, display cover layer 120, cover glass 120, layer 120, or exterior layer 120. Dielectric layer 122 may be formed from polymer, plastic, glass, ceramic, and/or other dielectric materials.

If desired, dielectric layer 122 may exhibit a dielectric constant that is lower than the dielectric constant of cover glass layer 120. This may configure dielectric layer 122 to form an impedance transition layer between air and cover glass layer 120 for the radio-frequency signals conveyed by antenna 50, helping to minimize signal reflections between the interior of device 10 and cover glass layer 120 and thus maximizing antenna efficiency. Dielectric layer 122 may also serve to limit radio-frequency exposure or absorption by external objects at the exterior of device 10, helping device 10 to satisfy regulatory requirements on radio-frequency energy exposure or absorption without backing off transmit power level.

If desired, dielectric layer 122 may include multiple plastic or polymer sub-layers that are molded, adhered, or coupled together. As one example, dielectric layer 122 may include a shroud having a ring-shaped trim portion that laterally surrounds the pixels in display 18A (e.g., that only extends around peripheral edge portions 42 of CGA 28 and that does not overlap display 18A) and may include a canopy portion that is coupled/adhered to the shroud portion and that overlaps or covers the pixels of display 18A. Dielectric layer 122 may sometimes also be referred to herein as dielectric member 122, dielectric cover layer 122, mask 122, shroud 122, trim 122, and/or canopy 122.

Antenna 50 may be at least partially disposed on or within CGA 28. As shown in FIG. 8, antenna 50 (e.g., antenna 50W-1, 50W-2, 50W, 50A, 50A-R, and/or 50A-L of FIGS. 4-6) may include an antenna conductor 126 layered onto a surface of CGA 28 (e.g., a three-dimensionally or compound curved surface). Antenna conductor 126 may form some or all of antenna resonating element 52 (FIG. 3). As such, the positive antenna feed terminal 56 of antenna 50 may be coupled to antenna conductor 126. The antenna resonating element may be a patch antenna resonating element, an inverted-F antenna resonating element, a dipole antenna resonating element, a monopole antenna resonating element, a planar inverted-F antenna resonating element, a slot antenna resonating element having edges defined by antenna conductor 126, and/or another type of antenna resonating element.

Antenna conductor 126 may be formed from conductive traces patterned onto the surface of CGA 28, conductive traces patterned onto a flexible printed circuit or another substrate that is pressed against or layered onto the surface of CGA 28, metal foil that is layered onto the surface of CGA 28, sheet metal (e.g., bent or curved sheet metal) that is pressed against the surface of CGA 28, and/or any other desired conductive (metal) materials disposed at, on, against, or along the surface of CGA 28. Antenna conductor 126 may include aluminum, stainless steel, copper, gold, silver, titanium, chromium, and/or any other desired metals and/or alloys.

In the example of FIG. 8, antenna conductor 126 is a curved conductor (e.g., a three-dimensionally curved or compound curved conductor) layered onto a curved interior surface of dielectric layer 122 (e.g., a three-dimensionally curved or compound curved surface of dielectric layer 122). As such, antenna conductor 126 extends parallel to and exhibits the same curvature as the interior surface of dielectric layer 122 or of dielectric layer 122 as a whole.

This is merely illustrative. Alternatively, antenna conductor 126 may be layered directly onto the interior surface of cover glass layer 120 (e.g., dielectric layer 122 may be omitted or antenna conductor 126 may be sandwiched between dielectric layer 122 and cover glass layer 120) or may be layered between the curved surfaces of two different dielectric layers 122. In these scenarios, antenna conductor 126 may extend parallel to and exhibit the same curvature as the interior surface of cover glass layer 120 and/or the surface(s) of dielectric layer(s) 122 (e.g., a three-dimensional or compound curvature). Alternatively, antenna conductor 126 may be layered onto or pressed against a planar portion of the surface of CGA 28 (e.g., dielectric layer 122 and/or cover glass layer 120).

CGA 28 may be mounted to outer chassis 12A using gasket 124. Gasket 124 may include conductive a ring of adhesive, an adhesive gasket, or any other desired material that affixes CGA 28 to outer chassis 12A. Outer chassis 12A and CGA 28 may surround an interior cavity of device 10. Inner chassis 12B (FIG. 2), which has been omitted from FIG. 8 for the sake of clarity, may be mounted to outer chassis 12A within the interior cavity. Logic board 38 may be mounted to the inner chassis within the interior cavity. If desired, conductive interconnect structures such as one or more conductive rivets or screws may mount, affix, secure, attach, or otherwise mechanically and/or electrically couple the inner chassis to outer chassis 12A.

As shown in FIG. 8, fan 41 may be mounted to logic board 38 (e.g., logic board 38 may be interposed between central portion 104 of fan 41 and CGA 28). Tunnel 106U extends from central portion 104 of fan cavity 92 to vent 39U in outer chassis 12A. Device 10 may include conductive structures 128 that overlap the lateral area of fan 41 and antenna conductor 126. Fan 41 may be interposed between conductive structures 128 and CGA 28 (antenna conductor 126). Conductive structures 128 may include conductive portions of other components in device 10 (e.g., displays 18B of FIG. 1, components mounted to logic board 38, components not mounted to logic board 38, conductive portions of the housing of device 10 such as the inner chassis and/or outer chassis 12A, and/or any other conductors in device 10).

Antenna conductor 126 may overlap tunnel 106U of fan 41. Antenna conductor 126 may be separated from fan 41 by height 134. If desired, antenna conductor 126 may be disposed on a dielectric substrate such as dielectric carrier 138. Dielectric carrier 138 may be a plastic bracket or other rigid structure that is mounted to fan 41 or that is otherwise interposed between CGA 28 and fan 41. Additionally or alternatively, dielectric carrier 138 may include a flexible or compressible biasing member such as a foam member (e.g., unidirectional structural foam), one or more springs, or any other desired biasing structures. The biasing member may produce a force that presses (biases) antenna conductor 126 against the surface of CGA 28 (e.g., given the rigidity of the fan housing). The biasing member may uniformly apply the force across the lateral area of antenna conductor 126. This may serve to maintain a strict spatial relationship and parallelism between the antenna resonating element in antenna 50 and CGA 28 even as device 10 is subject to wear or external force during use, thereby maintaining a clean and consistent gap and impedance transition between antenna 50 and CGA 28 across the lateral area of the antenna resonating element (e.g., given the compound curvature of CGA 28), minimizing signal reflection and maximizing antenna efficiency over the operating lifetime of device 10. In addition, mounting antenna 50 in device 10 in this way may place antenna 50 as close to the exterior of device 10 as possible, thereby maximizing the external field of view of the antenna. Alternatively, dielectric carrier 138 may be omitted and antenna conductor 126 may be printed onto the surface of CGA 28, embedded within CGA 28, or secured to the surface of CGA 28 using a layer of adhesive.

In general, the volume of antenna 50 (e.g., the radiating or resonant volume of antenna 50) is defined by the separation (e.g., parallel to the Y-axis) between antenna conductor 126 and the antenna ground for antenna 50 (e.g., antenna ground 54 of FIG. 3). In implementations where the entirety of fan housing 81 (FIG. 7) is formed from metal, the metal extends along tunnel 106U and under antenna conductor 126 to vent 39U. In these scenarios, antenna conductor 126 is separated from the antenna ground by height 134 and the electromagnetic volume of antenna 50 is therefore limited to volume 132 between fan 41 and CGA 28. This limits the overall efficiency bandwidth of antenna 50, thereby deteriorating wireless performance of device 10. To mitigate these issues, the volume of antenna 50 may be extended to also include some of the volume of fan cavity 92. Conversely, some of the volume of fan cavity 92 may form part of the radiating volume of antenna 50.

For example, as shown in FIG. 8, fan housing 108 (FIG. 7) may include metal housing portions 129M overlapping central portion 104 of fan cavity 92. Metal housing portions 129M define the edges/boundaries of central portion 104 of fan cavity 92. Metal housing portions 129M are sometimes also referred to herein as metal housing walls 81M of fan 41, metal fan housing walls 129M, or simply as metal walls 129M. Metal walls 129M may be formed from aluminum, stainless steel, titanium, copper, gold, silver, and/or any other desired conductive materials. Metal walls 129M may, for example, be formed from metal-plated plastic.

Rather than extending metal walls 129M all the way to vent 39U, fan housing 108 may also include dielectric housing portions 129D overlapping tunnel 106U. Dielectric housing portions 129D extend from the end of metal walls 129M to vent 39U. Dielectric housing portions 129D define the edges/boundaries of tunnel 106U (e.g., surround and enclose tunnel 106U). Port 109 is also formed between dielectric housing portions 129D. Dielectric housing portions 129D are sometimes also referred to herein as dielectric housing walls 129D of fan 41, dielectric fan housing walls 129D, or simply as dielectric walls 129D.

Dielectric walls 129D and thus tunnel 106U are vertically interposed between antenna conductor 126 and conductive structures 128 (e.g., conductive structures 128 may overlap tunnel 106U, antenna conductor 126, and dielectric walls 129D when viewed in the +Y direction). Dielectric carrier 138 may be mounted to the dielectric wall 129D facing CGA 28. Dielectric walls 129D may be formed from plastic, ceramic, glass, and/or any other desired materials. As one example, metal walls 129M and dielectric walls 129D may be formed from a single continuous piece of plastic that is provided with metal plating at metal walls 129M and without metal plating at dielectric walls 129D.

Dielectric walls 129D and metal walls 129M may be solid walls that direct air flow from central portion 104 through vent 39U, as shown by arrow 102. Fan blades 94 (FIG. 7) have been omitted from FIG. 8 for the sake of clarity. Fins 112 may be disposed within fan cavity 92 and may help direct air flow and/or facilitate thermal dissipation. If desired, fins 112 may be coupled or mounted (e.g., soldered or welded) to one or both metal walls 129M in fan 41.

Metal walls 129M, conductive material on logic board 38, and conductive structures 128 may all be coupled to a ground or reference potential. This configures metal walls 129M, the conductive material on logic board 38, and conductive structures 128 to collectively form some or all of the antenna ground 54 (FIG. 3) for antenna 50. In implementations where fins 112 are formed from metal, fins 112 may also be coupled to the ground potential to form part of the antenna ground for antenna 50.

By forming the portion of fan 41 overlapping antenna conductor 126 (e.g., dielectric walls 129D and tunnel 106U) from only dielectric materials, the portion of fan 41 overlapping antenna conductor 126 does not form part of the ground for antenna 50. The absence of conductive materials within the portion of fan 41 overlapping antenna 126 allows electromagnetic fields to freely pass between conductive structures 128 and antenna conductor 126, which extends the vertical separation between the antenna resonating element 52 (FIG. 3) (e.g., antenna conductor 126) and the antenna ground 54 (FIG. 3) of antenna 50 from height 134 to height 136. Put differently, this extends the radiating volume of antenna 50 from volume 132 to volume 130. The edges/boundaries of volume 130 (the antenna cavity) are defined by antenna conductor 126, conductive structures 128, outer chassis 12A, logic board 38, metal walls 129M, and optionally fins 112.

Whereas volume 132 includes only dielectric carrier 138, volume 130 includes both dielectric carrier 138 and tunnel 106U of fan 41. Volume 130 is sometimes also referred to herein as cavity 130 (e.g., an antenna cavity for antenna 50 that forms a cavity-back for antenna conductor 126). In this way, volume 130 (e.g., the antenna cavity for antenna 50) also includes some of fan cavity 92 (e.g., tunnel 106U). Conversely, some of fan cavity 92 (e.g., tunnel 106U) includes some of the antenna cavity (e.g., volume 130). In other words, antenna 50 is integrated into both CGA 28A and fan 41 (e.g., part of antenna 50 is formed from fan 41 and part of fan 41 is formed from antenna 50). This effectively maximizes the volume of antenna 50 and thus the efficiency bandwidth of antenna 50, given the constrained form factor of device 10 and the presence of a significant amount of conductive material around antenna 50 (e.g., display 18A, outer chassis 12A, conductive structures 128, logic board 38, metal walls 129M, etc.). If desired, the dimensions of volume 130 may be selected to contribute one or more resonant (e.g., standing wave) cavity modes to the radiative response of antenna 50 (e.g., in addition to maximizing efficiency bandwidth).

To further boost the efficiency bandwidth of antenna 50 in implementations where fins 112 are formed from metal, fins 112 may be disposed entirely or almost entirely within central portion 104 of fan cavity 92 (e.g., without extending into tunnel 106U, where the metal in the fins would otherwise reduce the volume 130 between antenna conductor 126 and conductive structures 128). Alternatively, fins 112 may be formed from dielectric material such as plastic. In these implementations, fins 112 may be disposed within or may extend into tunnels 106U (e.g., all the way to vent 39U or up to around line 144).

If desired, logic board 38 may include a cutout region that overlaps antenna conductor 126 so as to prevent conductive material on logic board 38 from overlapping antenna conductor 126 (e.g., when viewed in the +Y direction) and thus limiting the volume of antenna 50 to volume 132. Alternatively, logic board 38 may include a portion that extends into antenna volume 130 (e.g., overlapping antenna conductor 126 and tunnel 106U, such as up to around line 144) but that is free from ground traces, conductive components, and other conductive material.

If desired, a conductive material such as conductive mesh 140 may be disposed within fan cavity 92. Conductive mesh 140 may be coupled between opposing metal walls 129M of fan 41. Conductive mesh 140 may, for example, separate central portion 104 from tunnel 106U of fan cavity 92 (e.g., conductive mesh 140 may define the boundary between central portion 104 and tunnel 106U). Conductive mesh 140 may be opaque to electromagnetic energy at the frequencies of operation of antenna 50 while concurrently being transparent to air flow (e.g., breathable) from central portion 104 into tunnel 106U.

For example, conductive mesh 140 may include a grid or mesh of conductive material that is separated by openings. The openings may allow air to pass from central portion 104 into tunnel 106U, as shown by arrow 102. On the other hand, the openings may be sufficiently narrow (e.g., having a width or diameter less than or equal to ½, ⅓, ¼, ⅕, 1/10, or 1/15 the wavelength of operation of antenna 50). This may configure conductive mesh 140 to appear as a continuous conductive wall (e.g., an electromagnetic shield) for the radio-frequency signals conveyed by antenna 50. As such, conductive mesh 140 may block or reflect radio-frequency signals from passing into central portion 104 of fan cavity 92 (as shown by arrow 142) and may block or reflect radio-frequency signals from passing from central portion 104 into volume 130 (e.g., preventing other electromagnetic sources in device 10 from interfering with the operation of antenna 50), while concurrently allowing air to flow from central portion 104 and out vent 39U through tunnel 106U. Conductive mesh 140 may help to define one of the walls or edges of volume 130.

As used herein, the term “concurrent” means at least partially overlapping in time. In other words, first and second events are referred to herein as being “concurrent” with each other if at least some of the first event occurs at the same time as at least some of the second event (e.g., if at least some of the first event occurs during, while, or when at least some of the second event occurs). First and second events can be concurrent if the first and second events are simultaneous (e.g., if the entire duration of the first event overlaps the entire duration of the second event in time) but can also be concurrent if the first and second events are non-simultaneous (e.g., if the first event starts before or after the start of the second event, if the first event ends before or after the end of the second event, or if the first and second events are partially non-overlapping in time). As used herein, the term “while” is synonymous with “concurrent.”

Devices such as device 10 may gather and/or use personally identifiable information. It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

Physical environment: A physical environment refers to a physical world that people can sense and/or interact with without aid of electronic systems. Physical environments, such as a physical park, include physical articles, such as physical trees, physical buildings, and physical people. People can directly sense and/or interact with the physical environment, such as through sight, touch, hearing, taste, and smell.

Computer-generated reality: in contrast, a computer-generated reality (CGR) environment refers to a wholly or partially simulated environment that people sense and/or interact with via an electronic system. In CGR, a subset of a person's physical motions, or representations thereof, are tracked, and, in response, one or more characteristics of one or more virtual objects simulated in the CGR environment are adjusted in a manner that comports with at least one law of physics. For example, a CGR system may detect a person's head turning and, in response, adjust graphical content and an acoustic field presented to the person in a manner similar to how such views and sounds would change in a physical environment. In some situations (e.g., for accessibility reasons), adjustments to characteristic(s) of virtual object(s) in a CGR environment may be made in response to representations of physical motions (e.g., vocal commands). A person may sense and/or interact with a CGR object using any one of their senses, including sight, sound, touch, taste, and smell. For example, a person may sense and/or interact with audio objects that create 3D or spatial audio environment that provides the perception of point audio sources in 3D space. In another example, audio objects may enable audio transparency, which selectively incorporates ambient sounds from the physical environment with or without computer-generated audio. In some CGR environments, a person may sense and/or interact only with audio objects. Examples of CGR include virtual reality and mixed reality.

Virtual reality: A virtual reality (VR) environment refers to a simulated environment that is designed to be based entirely on computer-generated sensory inputs for one or more senses. A VR environment comprises a plurality of virtual objects with which a person may sense and/or interact. For example, computer-generated imagery of trees, buildings, and avatars representing people are examples of virtual objects. A person may sense and/or interact with virtual objects in the VR environment through a simulation of the person's presence within the computer-generated environment, and/or through a simulation of a subset of the person's physical movements within the computer-generated environment.

Mixed reality: In contrast to a VR environment, which is designed to be based entirely on computer-generated sensory inputs, a mixed reality (MR) environment refers to a simulated environment that is designed to incorporate sensory inputs from the physical environment, or a representation thereof, in addition to including computer-generated sensory inputs (e.g., virtual objects). On a virtuality continuum, a mixed reality environment is anywhere between, but not including, a wholly physical environment at one end and virtual reality environment at the other end. In some MR environments, computer-generated sensory inputs may respond to changes in sensory inputs from the physical environment. Also, some electronic systems for presenting an MR environment may track location and/or orientation with respect to the physical environment to enable virtual objects to interact with real objects (that is, physical articles from the physical environment or representations thereof). For example, a system may account for movements so that a virtual tree appears stationery with respect to the physical ground. Examples of mixed realities include augmented reality and augmented virtuality. Augmented reality: an augmented reality (AR) environment refers to a simulated environment in which one or more virtual objects are superimposed over a physical environment, or a representation thereof. For example, an electronic system for presenting an AR environment may have a transparent or translucent display through which a person may directly view the physical environment. The system may be configured to present virtual objects on the transparent or translucent display, so that a person, using the system, perceives the virtual objects superimposed over the physical environment. Alternatively, a system may have an opaque display and one or more imaging sensors that capture images or video of the physical environment, which are representations of the physical environment. The system composites the images or video with virtual objects, and presents the composition on the opaque display. A person, using the system, indirectly views the physical environment by way of the images or video of the physical environment, and perceives the virtual objects superimposed over the physical environment. As used herein, a video of the physical environment shown on an opaque display is called “pass-through video,” meaning a system uses one or more image sensor(s) to capture images of the physical environment, and uses those images in presenting the AR environment on the opaque display. Further alternatively, a system may have a projection system that projects virtual objects into the physical environment, for example, as a hologram or on a physical surface, so that a person, using the system, perceives the virtual objects superimposed over the physical environment. An augmented reality environment also refers to a simulated environment in which a representation of a physical environment is transformed by computer-generated sensory information. For example, in providing pass-through video, a system may transform one or more sensor images to impose a select perspective (e.g., viewpoint) different than the perspective captured by the imaging sensors. As another example, a representation of a physical environment may be transformed by graphically modifying (e.g., enlarging) portions thereof, such that the modified portion may be representative but not photorealistic versions of the originally captured images. As a further example, a representation of a physical environment may be transformed by graphically eliminating or obfuscating portions thereof. Augmented virtuality: an augmented virtuality (AV) environment refers to a simulated environment in which a virtual or computer generated environment incorporates one or more sensory inputs from the physical environment. The sensory inputs may be representations of one or more characteristics of the physical environment. For example, an AV park may have virtual trees and virtual buildings, but people with faces photorealistically reproduced from images taken of physical people. As another example, a virtual object may adopt a shape or color of a physical article imaged by one or more imaging sensors. As a further example, a virtual object may adopt shadows consistent with the position of the sun in the physical environment.

Hardware: there are many different types of electronic systems that enable a person to sense and/or interact with various CGR environments. Examples include head mounted systems, projection-based systems, heads-up displays (HUDs), vehicle windshields having integrated display capability, windows having integrated display capability, displays formed as lenses designed to be placed on a person's eyes (e.g., similar to contact lenses), headphones/earphones, speaker arrays, input systems (e.g., wearable or handheld controllers with or without haptic feedback), smartphones, tablets, and desktop/laptop computers. A head mounted system may have one or more speaker(s) and an integrated opaque display. Alternatively, a head mounted system may be configured to accept an external opaque display (e.g., a smartphone). The head mounted system may incorporate one or more imaging sensors to capture images or video of the physical environment, and/or one or more microphones to capture audio of the physical environment. Rather than an opaque display, a head mounted system may have a transparent or translucent display. The transparent or translucent display may have a medium through which light representative of images is directed to a person's eyes. The display may utilize digital light projection, OLEDs, LEDs, μLEDs, liquid crystal on silicon, laser scanning light sources, or any combination of these technologies. The medium may be an optical waveguide, a hologram medium, an optical combiner, an optical reflector, or any combination thereof. In one embodiment, the transparent or translucent display may be configured to become opaque selectively. Projection-based systems may employ retinal projection technology that projects graphical images onto a person's retina. Projection systems also may be configured to project virtual objects into the physical environment, for example, as a hologram or on a physical surface.

The foregoing is merely illustrative and various modifications can be made by those skilled in the art without departing from the scope and spirit of the described embodiments. The foregoing embodiments may be implemented individually or in any combination.

What is claimed is:

1. An electronic device comprising:
a housing having a vent;
a fan configured to convey air through the vent; and
an antenna having an antenna resonating element and an antenna ground, wherein a portion of the fan is interposed between the antenna resonating element and the antenna ground.

2. The electronic device of claim 1, wherein the fan comprises:
a fan housing that defines a central volume and a tunnel that extends from the central volume to the vent, the tunnel being interposed between the antenna resonating element and the antenna ground; and
fan blades disposed in the central volume.

3. The electronic device of claim 2, wherein the fan housing has metal walls overlapping the central volume and dielectric walls overlapping the tunnel.

4. The electronic device of claim 3, further comprising:
conductive structures, the dielectric walls being interposed between the conductive structures and the antenna resonating element, and the antenna ground comprising the conductive structures and the metal walls.

5. The electronic device of claim 4, further comprising:
a display that includes the conductive structures.

6. The electronic device of claim 4, further comprising:
a dielectric carrier mounted to the tunnel, the antenna resonating element being disposed on the dielectric carrier.

7. The electronic device of claim 6, further comprising:
a cover having a three-dimensional curvature, wherein the dielectric carrier presses the antenna resonating element against the cover.

8. The electronic device of claim 4, further comprising:
a logic board, wherein the fan housing is mounted to the logic board and the logic board has ground traces that form part of the antenna ground.

9. The electronic device of claim 3, the fan further comprising:
a conductive mesh coupled between the metal walls, wherein the conductive mesh is configured to pass the air and is electromagnetically opaque to radio-frequency signals conveyed by the antenna.

10. The electronic device of claim 3, further comprising:
fins disposed in the central volume and configured to direct flow of the air within the fan housing.

11. The electronic device of claim 10, wherein the fins comprise metal and are confined to the central volume.

12. The electronic device of claim 10, wherein the fins comprise plastic and extend into the tunnel.

13. An electronic device comprising:
a conductive chassis having a vent;
a cover mounted to the conductive chassis;
an antenna having an antenna resonating element layered onto the cover and having an antenna ground separated from the antenna resonating element by a cavity; and
a fan having blades and a shaft, the shaft extending from the blades to the vent through the cavity.

14. The electronic device of claim 13, wherein the blades are enclosed within metal walls, the shaft having dielectric walls that extend from the metal walls to the vent.

15. The electronic device of claim 14, wherein the shaft is free from metal.

16. The electronic device of claim 13, wherein the cover has a surface with a compound curvature and the antenna resonating element extends parallel to the surface.

17. The electronic device of claim 13, wherein the antenna is configured to convey radio-frequency signals at a frequency through the cover, the fan comprising:
a conductive mesh interposed between the blades and the shaft, wherein the conductive mesh is configured to pass air between the blades and the shaft and is electromagnetically opaque at the frequency.

18. A head-mounted device comprising:
a first conductive chassis;
a logic board mounted to the first conductive chassis;
first and second displays mounted to the logic board and configured to display respective left and right images;
a second conductive chassis that extends around the first conductive chassis and the logic board;
a cover mounted to the second conductive chassis opposite the first and second displays, the cover having a third display configured to display images through the cover;
an antenna having an antenna resonating element layered on a surface of the cover and having an antenna ground separated from the antenna resonating element by an antenna volume; and
a fan having walls that define a fan cavity and having blades disposed within the fan cavity, wherein a portion of the fan cavity forms part of the antenna volume.

19. The electronic device of claim 18, wherein the second conductive chassis comprises a vent, the walls extend to the vent, the blades are configured to exhaust air out the vent through the portion of the fan cavity, and the walls are free from conductive material within the antenna volume.

20. The electronic device of claim 18, further comprising a conductive mesh that is coupled between the walls and that separates the blades from the portion of the fan cavity.
